(19) United States
(12) Patent Application Publication
(10) Pub. No.: US 2026/0156837 A1
(43) Pub. Date: Jun. 4, 2026

(54) MEMORY DEVICE AND METHOD OF MANUFACTURING THE MEMORY DEVICE

(71) Applicant: SK hynix Inc., Icheon-si Gyeonggi-do (KR)

(72) Inventor: Sung Kun PARK, Icheon-si Gyeonggi-do (KR)

(73) Assignee: SK hynix Inc., Icheon-si Gyeonggi-do (KR)

(21) Appl. No.: 19/221,935

(22) Filed: May 29, 2025

(30) Foreign Application Priority Data
Nov. 29, 2024 (KR) 10-2024-0175002

(51) Int. Cl. H10B 80/00; H01L 23/00; H01L 25/00; H01L 25/065; H01L 25/18

(52) U.S. Cl. CPC H10B 80/00; H10W 90/00; H10W 80/312; H10W 80/327; H10W 90/792

(57) ABSTRACT

A memory device according to embodiments of the present disclosure includes a stack structure including conductive layers alternately stacked with interlayer insulating layers in a third direction, and an anti-bending structure overlapping the stack structure in a third direction. The anti-bending structure includes an auxiliary layer and impurity regions within the auxiliary layer and including an impurity injected into the auxiliary layer.

### CROSS-REFERENCE TO RELATED APPLICATION

The present application claims priority under 35 U.S.C. § 119(a) to Korean patent application number 10-2024-0175002 filed on Nov. 29, 2024, in the Korean Intellectual Property Office, the entire contents of which application is incorporated herein by reference.

### BACKGROUND

### 1. Technical Field

The present disclosure relates to a memory device and a method of manufacturing the memory device, including but not limited to a memory device including a memory block having a three-dimensional structure and a method of manufacturing the memory device.

### 2. Related Art

Memory devices include non-volatile memory devices that retain stored data even when power supply is absent or cut off. The non-volatile memory devices are classified as two-dimensional structures or three-dimensional structures according to the arrangement of memory cells. Memory cells of a non-volatile memory device having a two-dimensional structure are arranged in a single layer on a substrate, and memory cells of a non-volatile memory device having a three-dimensional structure are stacked in a vertical direction on the substrate. Because integration density of the non-volatile memory device having three-dimensional structures is higher than the integration density of the non-volatile memory device having two-dimensional structures, electronic devices using non-volatile memory devices having a three-dimensional structure have recently increased in popularity.

### SUMMARY

A memory device according to an embodiment of the present disclosure may include a stack structure including conductive layers alternately stacked with interlayer insulating layers in a third direction, and an anti-bending structure overlapping the stack structure in the third direction. The anti-bending structure may include an auxiliary layer and impurity regions within the auxiliary layer and including an impurity injected into the auxiliary layer.

A method of manufacturing a memory device according to an embodiment of the present disclosure may include forming an auxiliary layer on a substrate, injecting an impurity into the auxiliary layer to form impurity regions extending in a first direction, and forming a stack structure including conductive layers and interlayer insulating layers overlapping the auxiliary layer and the impurity regions.

A method of manufacturing a memory device according to an embodiment of the present disclosure may include forming a first auxiliary layer on a first substrate; injecting a first impurity into the first auxiliary layer to form first impurity regions extending in a first direction; forming a stack structure, including conductive layers and interlayer insulating layers, overlapping the first auxiliary layer in a third direction; forming a second auxiliary layer on a second substrate; injecting a second impurity into the second auxiliary layer to form second impurity regions extending in a second direction; forming a peripheral circuit structure overlapping the second auxiliary layer in the third direction; stacking the stack structure on the peripheral circuit structure; and removing the first substrate, the first auxiliary layer, and the first impurity regions.

A memory device according to an embodiment of the present disclosure may include a stack including conductive layers and interlayer insulating layers; and an anti-bending structure disposed on the stack structure and including an auxiliary layer comprising impurity regions formed from an impurity injected into the auxiliary layer.

### BRIEF DESCRIPTION OF THE DRAWINGS

FIG. 1 is a diagram illustrating a structure of a memory device according to an embodiment of the present disclosure;

FIG. 2 is a diagram illustrating a memory device according to an embodiment of the present disclosure;

FIG. 3A to FIG. 3C are diagrams illustrating an anti-bending structure according to an embodiment of the present disclosure;

FIG. 4A to FIG. 4C are diagrams illustrating an anti-bending structure according to an embodiment of the present disclosure;

FIG. 5A to FIG. 5C are diagrams illustrating anti-bending structures according to an embodiment of the present disclosure;

FIG. 6A and FIG. 6B are diagrams illustrating forms of impurity regions according to an embodiment of the present disclosure;

FIG. 7A to FIG. 7J are diagrams illustrating a memory device formed utilizing a method of manufacturing that reduces bending of a memory device according to an embodiment of the present disclosure;

FIG. 8 is a diagram illustrating a memory card system including a memory device according to an embodiment of the present disclosure; and

FIG. 9 is a diagram illustrating a solid state drive (SSD) system including the memory device according to an embodiment of the present disclosure.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

Terms such as “vertical,” “horizontal,” “below,” “over,” “overlap,” “flipped,” “on,” “side,” “upper,” “lower,” “higher,” “column,” “row,” “up,” “upward,” “upright,” “down,” “front,” “rear,” “level,” and other terms implying relative spatial relationship or orientation are utilized only for the purpose of ease of description or reference to a drawing and are not otherwise limiting. When one element is identified as “on” or “over” another element, the elements may directly contact each other or an intervening element may be disposed between the elements.

The cross-hatching throughout the figures illustrates corresponding or similar areas between the figures rather than indicating the materials associated with the areas.

When one element is identified as “coupled” to another element, the elements may be coupled directly or through at least one intervening element between the elements. When two elements are identified as “directly coupled,” one element is directly coupled to the other element without an intervening element between the two elements.

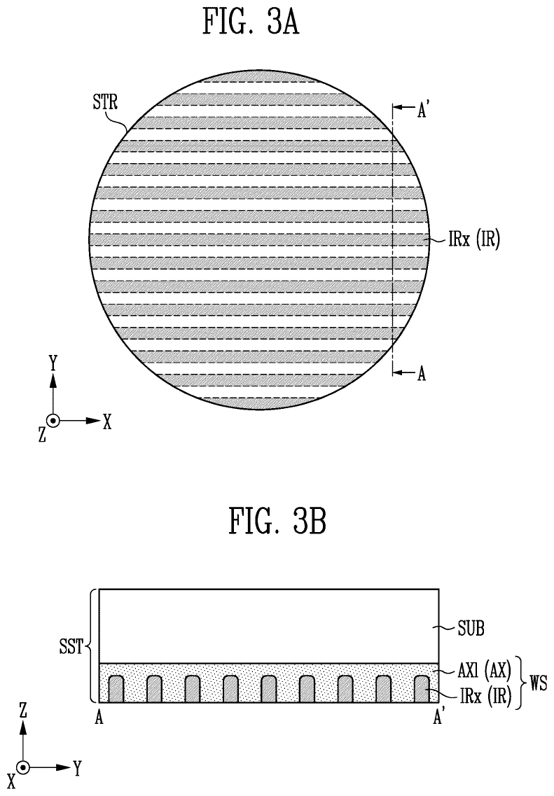

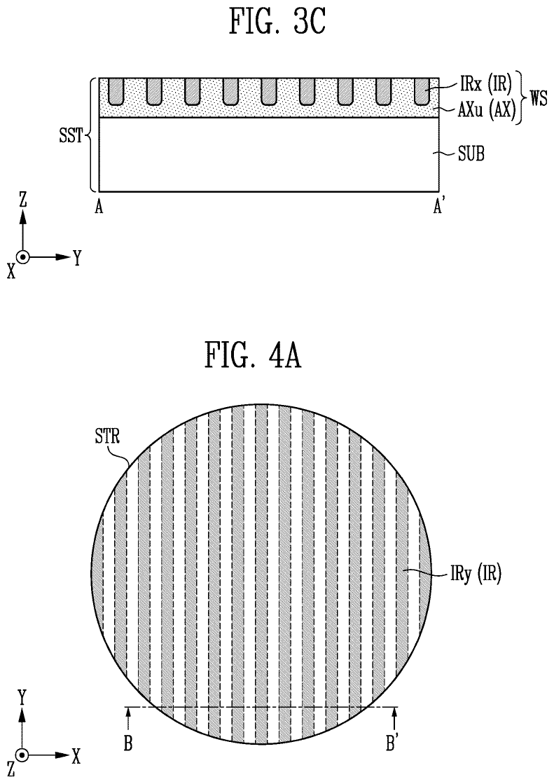

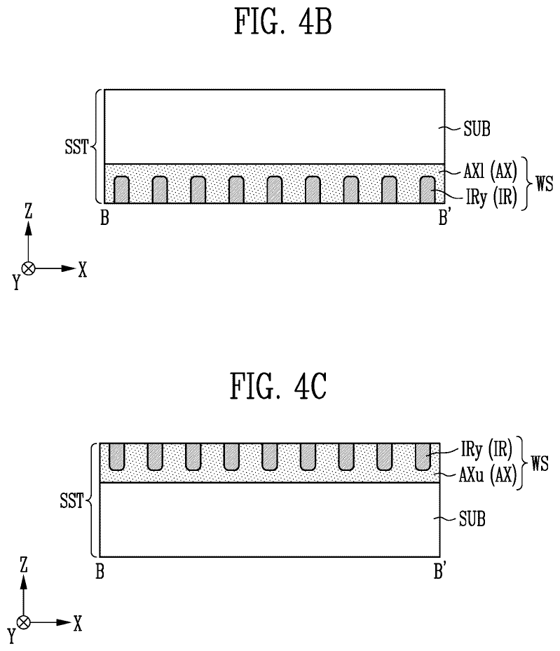

The drawings include reference names that indicate an element that is one of a plurality of elements that comprise the structure within parentheses next to the reference name. For example, IRx(IR) indicates a first impurity region IRx extending the X direction and is one of a plurality of elements that form the impurity region IR, such as shown in FIG. 3A through FIG. 3C. For example, IRy(IR) indicates a second impurity region IRy extending the Y direction and is one of a plurality of elements that form the impurity region IR, such as shown in FIG. 4A through FIG. 4C. For example, AX1(AX) indicates a first auxiliary layer AX1 and is one of a plurality of elements that form the auxiliary layer AX, such as shown, for example, in FIG. 3B. For example, AXu(AX) indicates a second auxiliary layer AXu and is one of a plurality of elements that form the auxiliary layer AX, such as shown, for example, in FIG. 3C.

The present disclosure describes a memory device in which warpage of a wafer and bending of a memory block may be reduced and a method of manufacturing the memory device.

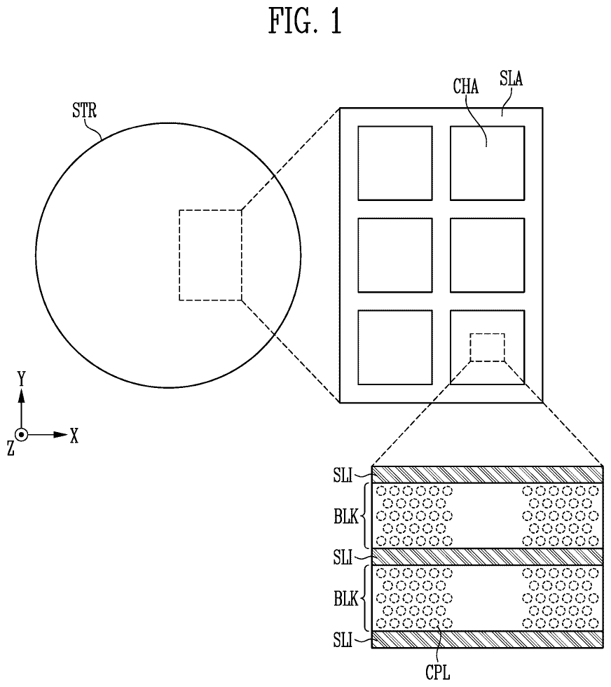

FIG. 1 is a diagram illustrating a structure of a memory device according to an embodiment of the present disclosure.

The semiconductor device includes a structure STR. For example, the structure STR includes a substrate, such as a silicon wafer, an SiGe wafer, an SOI wafer, and material patterns formed on the substrate.

Referring to FIG. 1, the structure STR includes chip regions CHA and a scribe lane region SLA. For example, the structure STR include chip regions CHA and a scribe lane region SLA surrounding the chip regions CHA.

The chip regions CHA are regions in which semiconductor chips are formed. The chip regions CHA are arranged along an X direction and a Y direction as shown in the drawings. Through a semiconductor integration process performed on the chip regions CHA, the semiconductor chips are formed. The semiconductor chips formed in each of the plurality of chip regions CHA in one structure STR may be substantially similar. After completion of the semiconductor integration process on the substrate, the chip regions CHA of the structure STR are separated, such that each semiconductor chip formed in the chip regions CHA is separated.

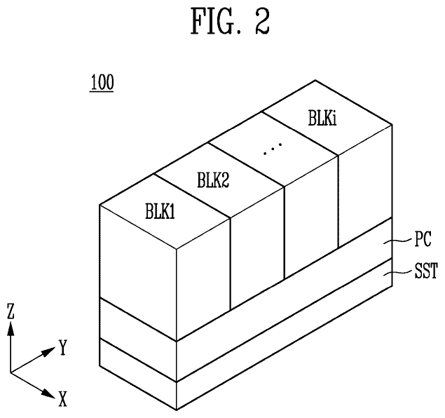

Each of the chip regions CHA includes memory blocks BLK, separators SLI separating consecutive memory blocks BLK, and cell plugs CPL formed in the memory blocks BLK. Each of the memory blocks BLK extends in the X direction. Consecutive memory blocks BLK in the Y direction are spaced apart by the separator SLI. Each of the separators SLI extends in the X direction. The cell plugs CPL extend through the memory blocks BLK. The cell plugs CPL extend in the Z direction. When components such as the memory blocks BLK are formed in the chip regions CHA, each of the separated semiconductor chips is referred to as a memory device. Details of the structure of the memory device are described with reference to FIG. 2.

The scribe lane region SLA is located outside of the chip areas CHA. For example, the scribe lane region SLA is located between the chip areas CHA. The scribe lane region SLA may surround the chip areas CHA. After the semiconductor integration process is completed, the scribe lane region SLA is cut during a dicing process to separate the semiconductor chips. Each of the chip regions CHA is separated by cutting the structure STR within or along the scribe lane region SLA. Each separate semiconductor chip includes one chip region CHA. A process for cutting the structure STR may include a method such as a sawing process using a blade, a cutting process using a laser, or a stealth dicing process. In an embodiment, electrical test patterns, process monitoring patterns, and alignment keys may be disposed in the scribe lane region SLA.

In FIG. 1, six chip regions CHA are shown for convenience of description, but the present disclosure is not limited to this example. For example, the structure STR may include at least seven chip regions CHA. The chip regions CHA and the scribe lane region SLA may be continuously formed throughout the structure STR, for example, utilizing a single continuous scribe lane region SLA throughout the structure STR. For example, an interface between each of the chip regions CHA and the scribe lane region SLA might not be clearly visible before the dicing process is performed. Positions of the chip regions CHA and the scribe lane region SLA within the structure STR may vary. In the present disclosure, the chip regions CHA and the scribe lane region SLA might not refer to regions within the substrate, but instead may refer to areas both within and on the substrate, where a horizontal range is limited to a specific range within the structure STR.

FIG. 2 is a diagram illustrating a memory device 100 according to an embodiment of the present disclosure.

Referring to FIG. 2, the memory device 100 is a chip region CHA resulting from separation of the chip regions CHA of FIG. 1. The memory device 100 includes a substructure SST, a peripheral circuit structure PC disposed on the substructure SST, and memory blocks BLK1 to BLKi, where i is an integer greater than 1. The memory blocks BLK1 to BLKi correspond to the memory blocks BLK of FIG. 1. The memory blocks BLK1 to BLKi are disposed over or overlap the peripheral circuit structure PC in the Z direction.

The substructure SST includes a substrate. The substrate may be a single crystalline semiconductor layer. For example, the substructure SST may include a bulk silicon substrate, a silicon on insulator substrate, a germanium substrate, a germane on insulator board, a silicon-germanium substrate, or an epitaxial thin layer formed through a selective epitaxial growth method.

The peripheral circuit structure PC includes, for example, a row decoder, a column decoder, a page buffer group, a control circuit, and so forth form circuits that control operation of the memory blocks BLK1 to BLKi. For example, the peripheral circuit structure PC includes NMOS transistors, PMOS transistors, resistors, capacitors, and so forth electrically coupled to the memory blocks BLK1 to BLKi. The peripheral circuit structure PC may be disposed between the substructure SST and the memory blocks BLK1 to BLKi.

Each of memory blocks BLK1 through BLKi includes a source structure, bit lines, cell strings electrically coupled to the source structure and bit lines, word lines electrically coupled to the cell strings, and select lines electrically coupled to the cell strings. Each of the cell strings includes memory cells and select transistors coupled in series by a cell plug CPL. Each of the select lines is used as a gate electrode of a corresponding select transistor, and each of the word lines is used as a gate electrode of a corresponding memory cell.

Each of the memory blocks BLK1 to BLKi extends in the X direction. The length in the X direction of each of the memory blocks BLK1 to BLKi may be greater than the length of each of the memory blocks BLK1 to BLKi in the Y direction. Because the memory blocks BLK1 to BLKi extend in the X direction, the word lines and the select lines included in the memory blocks BLK1 to BLKi extend in the X direction. Therefore, the stress in the X direction is different from the stress in the Y direction of the memory blocks BLK1 to BLKi. For example, the memory blocks BLK1 to BLKi may have a stress that expands in the X direction and a stress that contracts in the Y direction. According to the present disclosure, the memory device 100 does not bend or bends less compared to conventional technologies, despite the stresses caused by the memory blocks BLK1 to BLKi. In the present disclosure, curving the memory device 100 includes warpage or warping of wafers and bending of memory blocks. A configuration that reduces bending of the memory device 100 is described, for example, with reference to FIG. 3A.

In an embodiment, the substructure SST, the peripheral circuit structure PC, and the memory blocks BLK1 to BLKi may be stacked in a different order, including a reverse order, to the order shown in FIG. 2. For example, the peripheral circuit structure PC may be disposed between the memory blocks BLK1 to BLKi and the substructure SST.

In an embodiment, unlike shown in FIG. 2, the peripheral circuit structure PC may be disposed on a region of the substructure SST that does not overlap the memory blocks BLK1 to BLKi in the Z direction. For example, the peripheral circuit structure PC and the memory blocks BLK1 to BLKi may be distributed side-by-side in the Y direction or X direction or disposed on non-overlapping regions of the substructure SST in the Z-direction.

FIG. 3A to FIG. 3C are diagrams illustrating an anti-bending structure WS according to an embodiment of the present disclosure.

FIG. 3A to FIG. 3C each illustrate a view of the substructure SST of FIG. 2 of the structure STR of FIG. 1. FIG. 3B and FIG. 3C are cross-sectional views along line A-A′ of FIG. 3A.

Referring to FIG. 3A to FIG. 3C, the substructure SST of the structure STR includes a substrate SUB, an auxiliary layer AX, and an impurity region IR. In the present disclosure, the auxiliary layer AX and the impurity region IR are collectively referred to as an anti-bending structure WS. The substructure SST includes the substrate SUB and the anti-bending structure WS, and the anti-bending structure WS includes the auxiliary layer AX and the impurity regions IR. The memory device 100 includes a stack structure in which conductive layers are alternately stacked with interlayer insulating layers. The anti-bending structure WS is disposed on or overlaps the stack structure in the X direction and the Y direction.

The anti-bending structure WS may be disposed on, as shown in FIG. 3C, or under the substrate SUB, as shown in FIG. 3B. The auxiliary layer AX contacts an upper surface as shown in FIG. 3C, a lower surface as shown in FIG. 3B, or both the upper surface and the lower surface of the substrate SUB. The auxiliary layer AX may include a polysilicon or nitride layer. The auxiliary layer AX is referred to as a stressor layer. The impurity regions IR include impurities injected into the auxiliary layer AX. The impurities may include N-type impurities or P-type impurities. The impurity regions IR as formed apply a shrinkage stress or an expansion stress relative to or different from a stress applied by the auxiliary layer AX. The impurity regions IR extend in the X direction or the Y direction. The impurity regions IR may extend in a direction parallel to or perpendicular to the direction in which the memory blocks BLK extend.

Referring to FIG. 3A, each of the impurity regions IR extends in the X direction. The impurity regions IR extending in the X direction are referred to as first impurity regions IRx. Each of the first impurity regions IRx extend in the X direction. The first impurity regions IRx are spaced apart in the Y direction.

The first impurity regions IRx may extend in a direction parallel to the direction in which the memory blocks BLK of FIG. 1 and FIG. 2 extend. For example, the conductive layers included in the memory blocks BLK may extend in the X direction, and the first impurity regions IRx may extend in the X direction.

Referring to FIG. 3B, the anti-bending structure WS is disposed under the substrate SUB. The auxiliary layer AX is located under the substrate SUB. The auxiliary layer AX located under the substrate SUB is referred to as a first auxiliary layer AXI. The first auxiliary layer AXI is located between the first impurity regions IRx and the substrate SUB in the Z direction. The first auxiliary layer AXI contacts the lower surface of the substrate SUB.

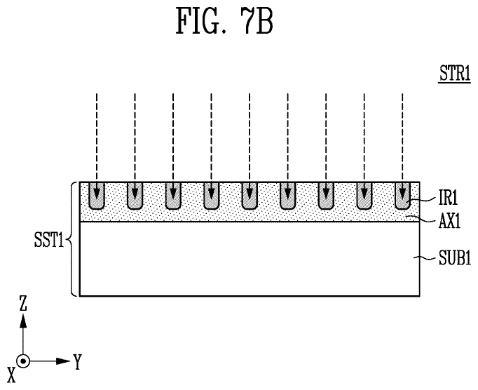

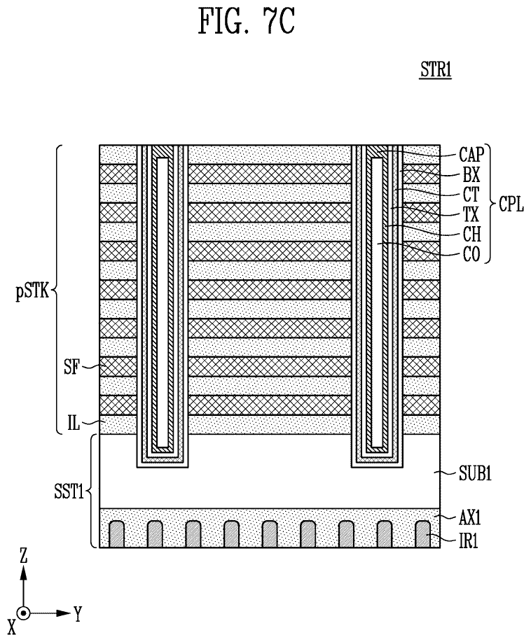

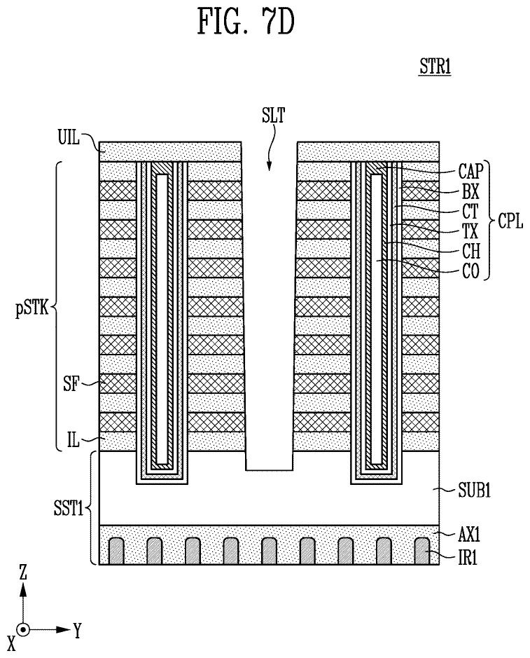

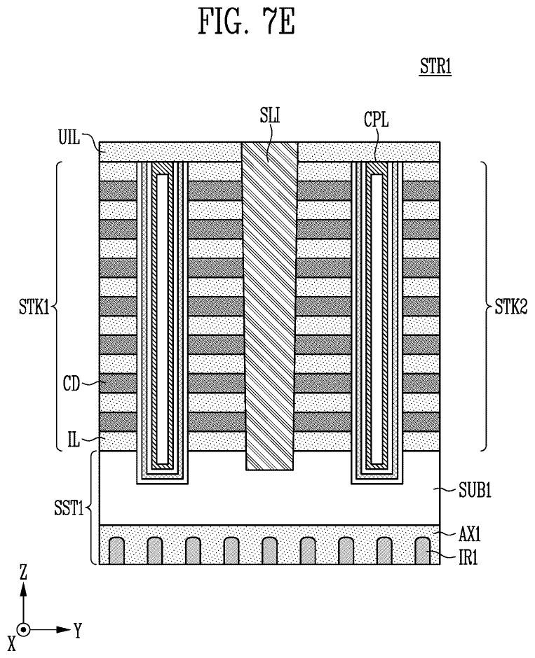

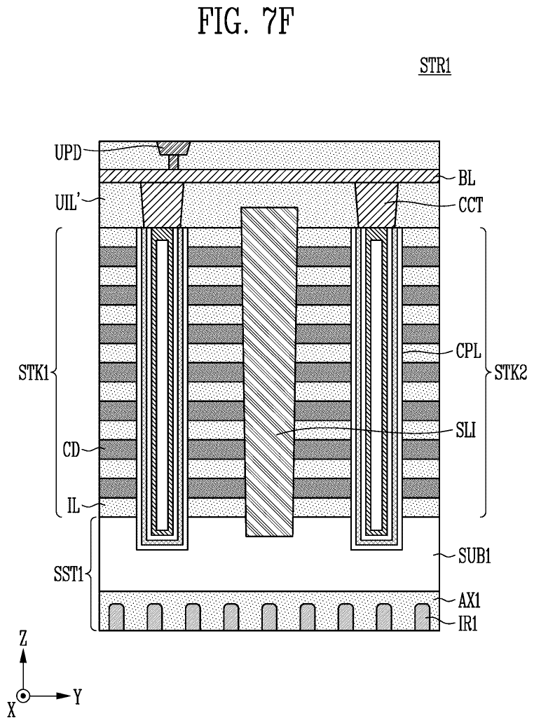

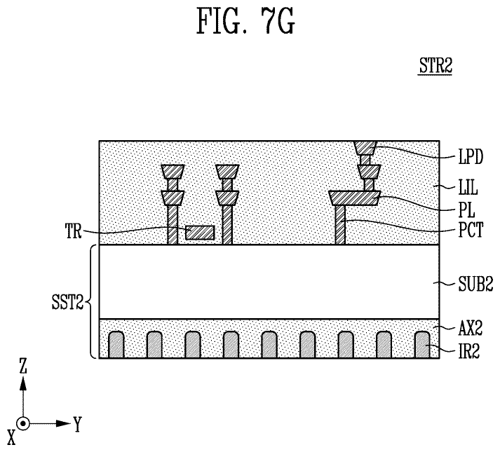

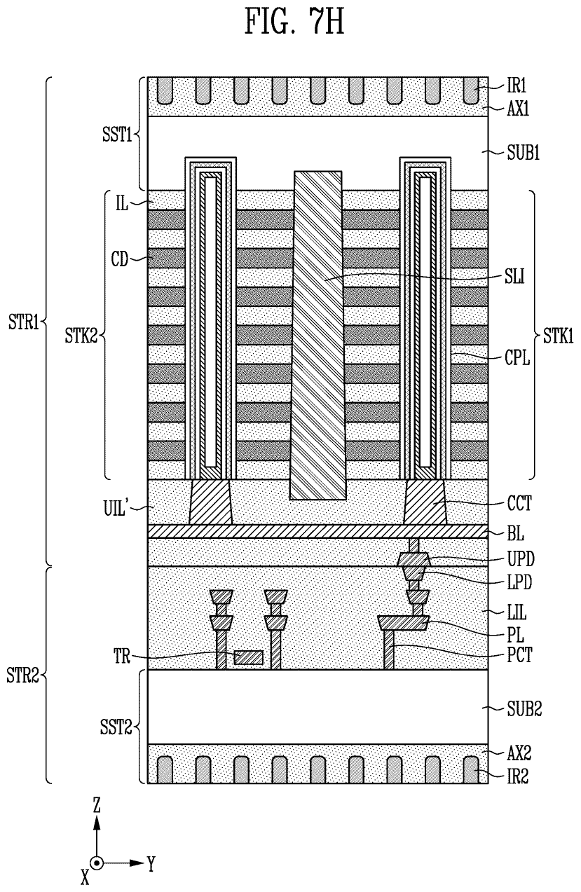

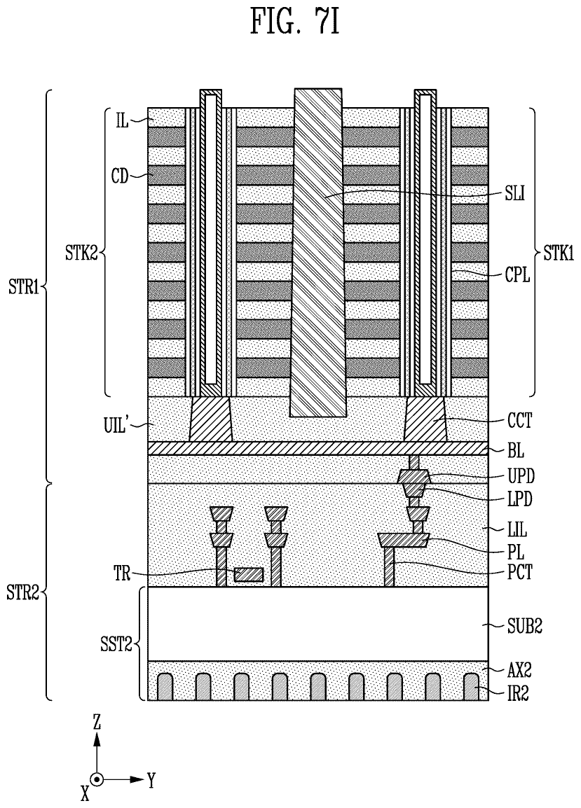

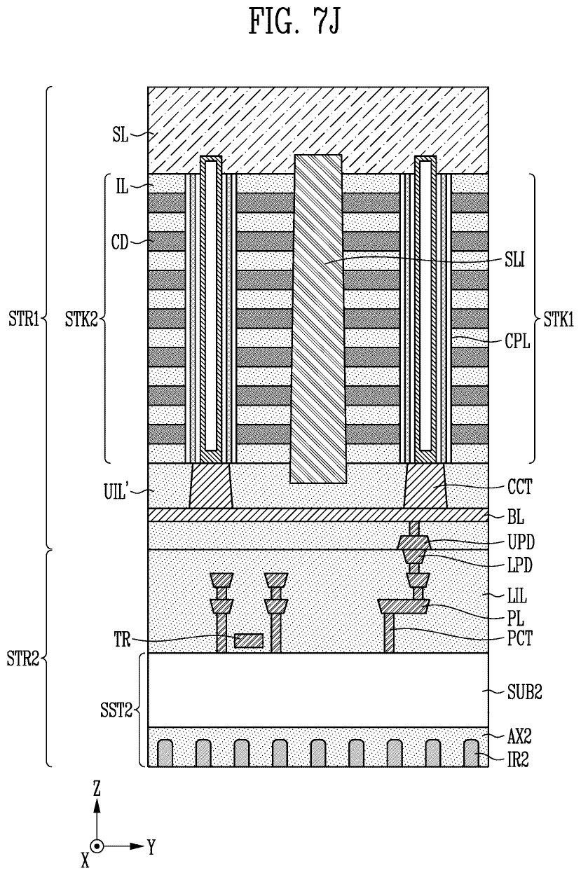

The first impurity regions IRx are located within the first auxiliary layer AXI. The first impurity regions IRx include an impurity injected into the first auxiliary layer Axl such as described with respect to FIG. 7B. The first impurity regions IRx extend from a level at a lower surface of the first auxiliary layer AXI toward the substrate SUB. The first impurity regions IRx are spaced apart from the substrate SUB. The length of the first impurity regions IRx in the Z direction is shorter than the length of the first auxiliary layer AXI in the Z direction.

Referring to FIG. 3C, the anti-bending structure WS is disposed on the substrate SUB. The auxiliary layer AX is located on the substrate SUB. The auxiliary layer AX located on or over the substrate SUB is referred to as a second auxiliary layer AXu. The second auxiliary layer AXu is located between the substrate SUB and the first impurity regions IRx in the Z direction. The second auxiliary layer AXu contacts the upper surface of the substrate SUB.

The first impurity regions IRx are located within the second auxiliary layer AXu. The first impurity regions IRx include an impurity injected into the second auxiliary layer AXu such as described with respect to FIG. 7B. The first impurity regions IRx extend from a level at an upper surface of the second auxiliary layer AXu toward the substrate SUB. The first impurity regions IRx are spaced apart from the substrate SUB. The length of the first impurity regions IRx is shorter than the length of the second auxiliary layer AXu in the Z direction.

In FIG. 3A to FIG. 3C, the first impurity regions IRx apply a stress that causes shrinkage that is different from, and greater than, the stress applied or caused by the auxiliary layer AX. Different types of impurities are injected such that the first impurity regions IRx apply a greater shrinkage stress compared to the stress applied by the auxiliary layer AX. For example, the first impurity regions IRx may have reduced volume compared to the volume of the auxiliary layer AX due to impurities included in the first impurity regions IRx. Therefore, when the memory blocks BLK apply a stress that causes expansion in the X direction due to the conductive layers extending in the X direction, the memory device 100 does not bend or bends less compared to conventional technologies, due to the first impurity regions IRx causing the shrinkage stress.

In an embodiment, as shown in FIG. 3A, the first impurity regions IRx are formed having a uniform pattern within the entire region of the structure STR. In an alternative embodiment, the first impurity regions IRx are formed to have different patterns depending on the location of the first impurity regions IR on the structure STR. The first impurity regions IRx may be formed in some but not all regions of the structure STR. For example, the first impurity regions IRx may be formed in the chip regions CHA and not formed in the scribe lane region SLA. For example, the first impurity regions IRx may be formed in the scribe lane region SLA and not formed in the chip region CHA. For example, the first impurity regions IRx may be formed in some but not all of the chip region CHA and not formed in the scribe lane region SLA. For example, the first impurity regions IRx may be formed over the chip region CHA and the scribe lane region SLA in a specific area in the structure STR and may be formed in some but not all of the chip region CHA and in the scribe lane region SLA in areas other than the specific area in the structure STR.

FIG. 4A to FIG. 4C are diagrams illustrating the anti-bending structure WS according to an embodiment of the present disclosure.

FIG. 4B and FIG. 4C are cross-sectional views illustrating the cross-section B-B′ of FIG. 4A. The configurations shown in FIG. 4A to FIG. 4C have similarities to the configurations described with reference to FIG. 3A to FIG. 3C. The anti-bending structure WS of FIG. 3A to FIG. 3C has similar features to the anti-bending structure WS of FIG. 4A to FIG. 4C.

Referring to FIG. 4A, each of the impurity regions IR extends in the Y direction. The impurity regions IR extending in the Y direction are referred to as second impurity regions IRy. Each of the second impurity regions IRy extends in the Y direction. The second impurity regions IRy are spaced apart in the X direction.

The second impurity regions IRy extend in a direction perpendicular to the direction in which the memory blocks BLK of FIG. 1 and FIG. 2 extend. For example, when the conductive layers included in the memory blocks BLK extend in the X direction, the second impurity regions IRy extend in the Y direction.

Referring to FIG. 4B, the anti-bending structure WS is disposed under the substrate SUB. The first auxiliary layer AXI is located under the substrate SUB. The first auxiliary layer AXI is located between the first impurity regions IRx and the substrate SUB in the Z direction. The first auxiliary layer AXI contacts the lower surface of the substrate SUB.

The second impurity regions IRy are located within the first auxiliary layer AXI. The second impurity regions IRy include the impurity injected into the first auxiliary layer AXI such as described with respect to FIG. 7B. The second impurity regions IRy extend from a level at the lower surface of the first auxiliary layer AXI toward the substrate SUB. The second impurity regions IRy are spaced apart from the substrate SUB. The length of the second impurity regions IRy in the Z direction is shorter than the length of the first auxiliary layer AXI in the Z direction.

Referring to FIG. 4C, the anti-bending structure WS is disposed on the substrate SUB. The second auxiliary layer AXu is located on or over the substrate SUB. The second auxiliary layer AXu is located between the substrate SUB and the second impurity regions IRy in the Z direction. The second auxiliary layer AXu contacts the upper surface of the substrate SUB.

The second impurity regions IRy are located in the second auxiliary layer AXu. The second impurity regions IRy include the impurity injected into the second auxiliary layer AXu. The second impurity regions IRy extend from a level at the upper surface of the second auxiliary layer AXu toward the substrate SUB. The second impurity regions IRy are spaced apart from the substrate SUB. The length of the second impurity regions IRy is shorter than the length of the second auxiliary layer AXu in the Z direction.

In FIG. 4A to FIG. 4C, the second impurity regions IRy apply a stress that causes expansion that is different from, and greater than, the stress applied by the auxiliary layer AX. Different types of impurities are injected such that the second impurity regions IRy apply a greater expansion stress relative to the stress applied by the auxiliary layer AX. The impurities included in the first impurity regions IRx and the impurities included in the second impurity regions IRy may be different kinds of impurities. For example, the second impurity regions IRy may have increased volume compared to the volume of the auxiliary layer AX due to impurities included in the second impurity regions IRy. Therefore, when the memory blocks BLK apply a stress that causes contraction in the Y direction due to the conductive layers extending in the X direction, the memory device 100 does not bend or bends less compared to conventional technologies, due to the second impurity regions IRy applying expansion stress.

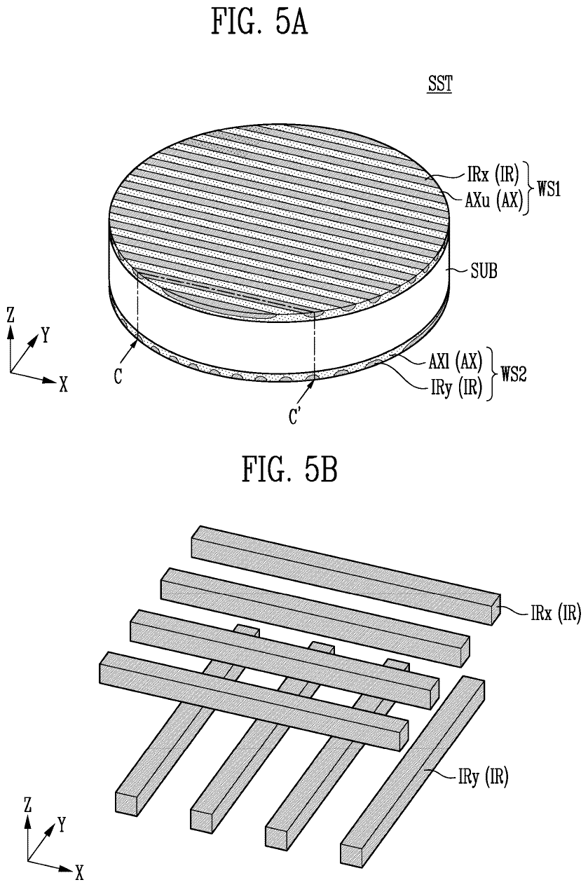

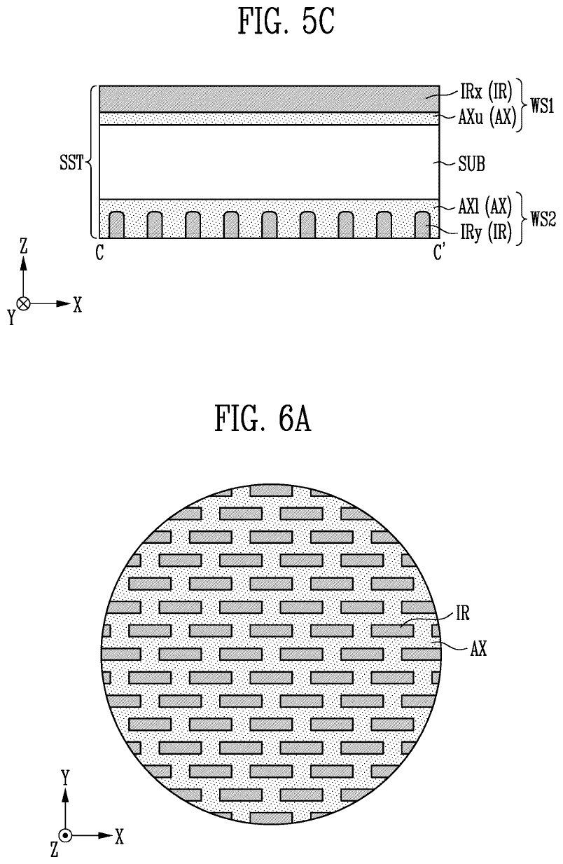

Referring to FIG. 3A to FIG. 3C and FIG. 4A to FIG. 4C, the impurity regions IR are formed on an XY plane. For example, because the memory blocks BLK included in a 3D NAND memory device have an asymmetric form in the XY plane, stresses in the X direction are different from stresses in the Y direction of the memory blocks BLK. According to the present disclosure, the impurity regions IR extend in the X direction or the Y direction apply stresses to compensate for stresses in the X direction of the memory blocks BLK and stresses in the Y direction of the memory blocks BLK, respectively. The first impurity regions IRx applying shrinkage stress in the X direction are formed to compensate for expansion stress caused by the memory blocks BLK in the X direction. Alternatively, the second impurity regions IRy causing expansion stress in the Y direction are formed to compensate for shrinkage stress of the memory blocks BLK in the Y direction. Alternatively, both the impurity regions IRx and IRy may be included in the substructure SST. An embodiment in which both the impurity regions IRx and IRy are included in the substructure SST is described with reference to FIG. 5A to FIG. 5C.

FIG. 5A to FIG. 5C are diagrams illustrating the anti-bending structures WC according to an embodiment of the present disclosure.

The configurations shown in FIG. 5A to FIG. 5C have similarities to the configurations described with reference to FIG. 3A to FIG. 3C and FIG. 4A to FIG. 4C. For example, the description of the anti-bending structure WS described in connection with FIG. 3A to FIG. 3C and FIG. 4A to FIG. 4C may apply to the anti-bending structures WS1 and WS2 of FIG. 5A to FIG. 5C.

Referring to FIG. 5A to FIG. 5C, the substructure SST includes a first anti-bending structure WS1 spaced apart from a second anti-bending structure WS2 by the substrate SUB. The first anti-bending structure WS1 is disposed on the substrate SUB, and the second anti-bending structure WS2 is disposed under the substrate SUB.

The first anti-bending structure WS1 includes the first impurity regions IRx located in the second auxiliary layer AXu. The first impurity regions IRx included in the first anti-bending structure WS1 extend in the X direction. The second anti-bending structure WS2 include the second impurity regions IRy located in the first auxiliary layer AXI. The second impurity regions IRy included in the second anti-bending structure WS2 each extend in the Y direction. The first impurity regions IRx included in the first anti-bending structure WS1 and the second impurity regions IRy included in the second anti-bending structure WS2 extend in directions perpendicular to each other.

According to FIG. 5A to FIG. 5C, the expansion stress in the X direction is compensated for by the shrinkage stress in the Y direction of the memory blocks BLK. For example, the stress caused by the first impurity regions IRx included in the first anti-bending structure WS1 compensates for the expansion stress caused by the memory blocks BLK in the X direction, such that the bending of the memory device 100 in the X direction is reduced. The stress caused by the second impurity regions IRy included in the second anti-bending structure WS2 compensate for the shrinkage stress caused the memory blocks BLK in the Y direction, such that bending of the memory device 100 in the Y direction is reduced. Compared to the example where one anti-bending structure WS is included in substructure SST, the bending of the memory device 100 is further reduced when both the first anti-bending structure WS1 and the second anti-bending structure WS2 are included in the substructure SST.

According to the present disclosure, because the bending of the memory device 100 is reduced, defects that may occur when the memory device 100 bends may be reduced, for example, cracks in the memory device, defects in which components included in the memory device are not aligned, and the like. According to the present disclosure, because bending of the memory device 100 is reduced by using the impurity regions IR during an impurity implantation process without adding a separate structure, side effects may be reduced compared to examples when a separate structure is added.

Unlike the impurity regions IR shown in FIG. 5A to FIG. 5C, the second impurity regions IRy extending in the Y direction may be located on the substrate SUB, and the first impurity regions IRx extending in the X direction may be located under the substrate SUB.

In an embodiment, different kinds of impurities may be injected into the auxiliary layer AX disposed on or under the substrate SUB to form the first impurity regions IRx and the second impurity regions IRy.

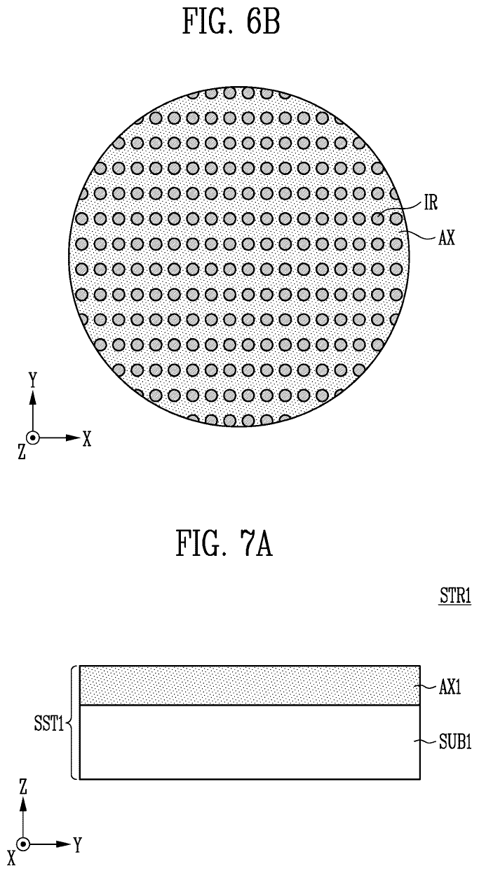

Referring to FIG. 3A to FIG. 3C, FIG. 4A to FIG. 4C, and FIG. 5A to FIG. 5C, the impurity regions IR formed in the auxiliary layer AX have a stripe shape extending in the X direction or the Y direction. The scope of the present disclosure is not limited to this example. For example, the impurity regions IR my extend in the X direction or the Y direction or in a combination of the X direction and the Y direction. The impurity regions IR in various forms are described with reference to FIG. 6A and FIG. 6B.

FIG. 6A and FIG. 6B are diagrams illustrating a form of impurity regions IR according to various embodiments of the present disclosure.

The configurations shown in FIGS. 6A and 6B have similarities to the configurations described with reference to FIG. 3A to FIG. 3C, FIG. 4A to FIG. 4C, and FIG. 5A to FIG. 5C. For example, the description of the auxiliary layer AX and the impurity regions IR described with reference to FIG. 3A to FIG. 3C, FIG. 4A to FIG. 4C, and FIG. 5A to FIG. 5C may apply to the auxiliary layer AX and the impurity regions IR of FIG. 6A and FIG. 6B.

Referring to FIG. 6A, the impurity regions IR are arranged in a dash form within the auxiliary layer AX. Each of the impurity regions IR has a rectangular planar shape with a major axis in the X direction and a minor axis in the Y direction. Each of the impurity regions IR are spaced apart in the X direction and spaced apart in the Y direction. Consecutive rows of the impurity regions IR in the X direction are not aligned in the Y direction.

Unlike the impurity regions IR shown in FIG. 6A, the impurity regions IR may have a major axis in the Y direction and a minor axis in the X direction. The planar shape of each of the impurity regions IR may vary, such as a rectangular shape, an elliptical shape, and a rectangular shape with rounded corners. The impurity regions IR may be arranged parallel to each other in the Y direction without alignment between consecutive columns. The impurity regions IR may include impurity regions IR extending in any one direction.

Referring to FIG. 6B, the impurity regions IR be formed in round or elliptical shapes arranged in the X direction in the auxiliary layer AX. Each of the impurity regions IR may be circular in a plan view. When the distance between adjacent impurity regions IR in the X direction is shorter than the distance between adjacent impurity regions IR in the Y direction, the impurity region IR are referred to as having a form extending in the X direction.

FIG. 6A and FIG. 6B illustrate various embodiments where the impurity regions IR extend in the X direction, but the present disclosure is not limited to these examples. For example, when the impurity regions IR extend in the Y direction, the impurity regions IR may be formed as dashes or arranged circles. The auxiliary layer AX in FIG. 6A and FIG. 6B may be the first auxiliary layer AXI or the second auxiliary layer AXu.

The impurity regions IR may be arranged in various forms in the auxiliary layer AX other than as shown in FIG. 6A and FIG. 6B. In an embodiment, the impurity regions IR do not form a uniform pattern throughout the entire region of the wafer, and the impurity region IR may be formed only in one or more sections of the wafer. For example, impurity regions IR may be formed in the chip regions CHA and not in the scribe lane region SLA. For example, the impurity regions IR may be formed in the scribe lane region SLA and not in the chip regions CHA. For example, the impurity regions IR may be formed in some but not all of the chip regions CHA and not formed in the scribe lane region SLA. For example, the impurity regions IR may be formed over the chip region CHA and the scribe lane region SLA in a specific area in the structure STR and may be formed in some but not all of the chip region CHA and in the scribe lane region SLA in areas other than the specific area in the structure STR.

In an embodiment, the depth, the planar area, or the impurity concentration of the impurity regions IR may vary depending on the location on the wafer. In an embodiment, the planar shape of the impurity regions IR may vary depending on the location on the wafer.

FIG. 7A to FIG. 7J are diagrams illustrating a memory device formed utilizing a method of manufacturing that reduces bending of the memory device 100 according to an embodiment of the present disclosure.

The method of manufacturing the memory device described with reference to FIG. 7A to FIG. 7J relates to an example of the anti-bending structure WS according to the present disclosure. The anti-bending structure WS of the present disclosure may be utilized in various types of memory devices in addition to the embodiment described with respect to FIG. 7A to FIG. 7J. The method described with reference to FIG. 7A to FIG. 7J shows formation of a first structure STR1 and a second structure STR2 in various stages.

Referring to FIG. 7A, a first substructure SST1 included in a first structure STR1 is formed. The first substructure SST1 includes an auxiliary layer AX1 formed on a first substrate SUB1. The auxiliary layer AX1 is formed on an upper surface of the first substrate SUB1 in this example.

Referring to FIG. 7B, impurities are injected into the auxiliary layer AX1 included in the first substructure SST1 to form impurity regions IR1. The impurity regions IR1 include the impurities injected into the auxiliary layer AX1. In an embodiment, the impurity regions IR1 extend in the X direction, such as the first impurity region IRx shown in FIG. 3A. In an alternative embodiment, the impurity regions IR1 extend in the Y direction, such as the second impurity regions IRy shown in FIG. 4A. In this example, the impurity regions IR1 extend in the X direction, similar to the first impurity regions IRx.

Although not shown, additional processes may be performed to form the impurity regions IR1 included in the first structure STR1. For example, a photoresist layer may be formed on the auxiliary layer AX1 formed on the first substrate SUB1. The photoresist layer may cover the auxiliary layer AX1. A portion of the photoresist layer may be removed through a photolithography process. As the portion of the photoresist layer is removed, a photoresist pattern including openings is formed. The auxiliary layer AX1 is exposed through the openings in the photoresist pattern. Impurities are injected into some regions of the auxiliary layer AX1 using the photoresist pattern. For example, the impurities may be injected into a region of the auxiliary layer AX1 exposed through the openings in the photoresist pattern to form the impurity regions IR1. The photoresist pattern may be removed.

Referring to FIG. 7C, the first substructure SST1 is vertically flipped or inverted in the Z direction. After vertical inversion, an upper surface of the first substrate SUB1 is the upper surface of the first substructure SST1. The auxiliary layer AX1 and the impurity regions IR1 are located along the lower surface of the first substrate SUB1, under the first substrate SUB1. FIG. 7C shows an example, and the first substructure SST1 might not be vertically flipped, in which example the auxiliary layer AX1 is located on the upper surface of the first substrate SUB1, similar to the second auxiliary layer AXu shown in FIG. 3C and FIG. 4C.

A preliminary stack structure pSTK is formed on the first substructure SST1. The preliminary stack structure pSTK extends in the Z direction from the first substrate SUB1 of first substructure SST1, and the first substrate SUB1 is located between the preliminary stack structure pSTK and the auxiliary layer AX1 including the impurity regions IR1. Alternatively, the preliminary stack structure pSTK extends from the from the auxiliary layer AX1 and the impurity regions IR1 of first substructure SST1, such that the auxiliary layer AX1 is located between the preliminary stack structure pSTK and the first substrate SUB1.

The preliminary stack structure pSTK includes interlayer insulating layers IL and sacrificial layers SF stacked on the first substructure SST1. The interlayer insulating layers IL are alternately stacked with the sacrificial layers SF in the Z direction. The interlayer insulating layers IL and the sacrificial layers SF may overlap with the auxiliary layer AX1 and the impurity regions IR1 in the Z direction. The interlayer insulating layers IL and the sacrificial layers SF may cover the auxiliary layer AX1 and the impurity regions IR1.

The interlayer insulating layers IL may include an insulating material. For example, the interlayer insulating layers IL may include an oxide layer, for example, a silicon oxide layer. The sacrificial layers SF include a material that may be selectively removed in a subsequent process. The sacrificial layers SF may include a material having an etching selectivity different from the etching selectively of the interlayer insulating layers IL. For example, the sacrificial layers SF may include a nitride layer.

The cell plugs CPL are formed in some regions of the first structure STR1. The cell plugs CPL extend through the interlayer insulating layers IL and the sacrificial layers SF of the preliminary stack structure pSTK. The cell plugs CPL extend in the Z direction. Each of the cell plugs CPL extend into the first substrate SUB1. A lower end of each of the cell plugs CPL is located within the first substrate SUB1. The cell plugs CPL are arranged in the X and Y directions.

Each of the cell plugs CPL includes a blocking layer BX contacting a side surface of the preliminary stack structure pSTK, a charge trapping layer CT extending along an inner surface of the blocking layer BX, a tunneling layer TX extending along an inner surface of the charge trapping layer CT, a channel layer CH extending along an inner surface of the tunneling layer TX, a core pillar CO disposed within the channel layer CH, and a capping layer CAP contacting the channel layer CH and the core pillar CO. The blocking layer BX, the charge trapping layer CT, the tunneling layer TX, the channel layer CH, and the core pillar CO extend in the Z direction. The blocking layer BX, the charge trapping layer CT, the tunneling layer TX, the channel layer CH, and the core pillar CO extends through the preliminary stack structure pSTK.

Referring to FIG. 7D, an upper insulating layer UIL is formed on the preliminary stack structure pSTK. The upper insulating layer UIL covers the cell plugs CPL such that an upper end of the cell plugs CPL is not exposed. The upper insulating layer UIL covers an upper surface of the cell plugs CPL. The upper insulating layer UIL may include an oxide layer.

A slit SLT is formed extending through the first structure STR1. The slit SLT extends in the Z direction. The slit SLT may be formed by etching a section of each of the interlayer insulating layers IL and the sacrificial layers SF. An anisotropic dry etching process may be performed to form the slit SLT at a specific location. The slit SLT extends in the X direction. The first structure STR1 is separated into stack structures spaced apart in the Y direction by the slit SLT.

A section of the first substrate SUB1 is exposed through the slit SLT. An area of an upper surface of the first substrate SUB1 is etched when the slit SLT is formed.

Referring to FIG. 7E, the sacrificial layers SF are replaced with conductive layers CD through the slit SLT. The conductive layers CD may include at least one of tungsten (W), cobalt (Co), nickel (Ni), molybdenum (Mo), silicon (Si), and polysilicon (poly-Si). The conductive layers CD may be used as the word lines and select lines such as described with reference to FIG. 2. The conductive layers CD and the interlayer insulating layers IL may overlap the auxiliary layer AX1 and the impurity regions IR1 in the Z direction.

A separator SLI is formed in the slit SLT. The separator SLI includes a separator material layer that fills the slit SLT. The separator material layer may include a single layer or multiple layers. For example, the separator SLI may include an insulating material filled in the slit SLT.

The first structure STR1 includes a first stack structure STK1 spaced apart from a second stack structure STK2 in the Y direction. The first stack structure STK1 is separated from the second stack structure STK2 by the separator SLI. The stack structures STK1 and STK2 correspond to the memory blocks BLK1 and BLK2 of FIG. 2. The conductive layers CD included in the first stack structure STK1 are insulated from the conductive layers CD included in the second stack structure STK2. The conductive layers CD included in the stack structures STK1 and STK2 extend in the X direction between separators SLI extending in the X direction. For example, the conductive layers CD extend in a direction parallel to the impurity regions IR1.

Because each of the conductive layers CD has a shape extending in the X direction, the stack structures STK1 and STK2 apply stress that cause expansion in the X direction. Warpage of the first structure STR1 may be prevented or mitigated by stresses caused by the impurity regions IR1 of the first substructure SST1, which stresses compensate for the expansion stress.

Referring to FIG. 7F, an additional insulating material is deposited on the upper insulating layer UIL to form an upper insulating layer UIL′. Cell contacts CCT, a bit line BL, and an upper pad UPD are formed in the upper insulating layer UIL′. A bit line BL is coupled to each of the cell plugs CPL via each of the cell contacts CCT. The upper pad UPD is exposed through the upper surface of the first structure STR1. The cell contacts CCT, the bit line BL, and the upper pad UPD may each include a conductive material.

Referring to FIG. 7G, a second structure STR2 is formed. The second structure STR2 includes a second substructure SST2. The second substructure SST2 includes an auxiliary layer AX2 and impurity regions IR2 formed on one surface of the second substrate SUB2. In FIG. 7G, the auxiliary layer AX2 and the impurity regions IR2 included in the second substructure SST2 correspond to the embodiment of FIG. 3B, although the present disclosure is not limited to this example. For example, the second substructure SST2 includes an anti-bending structure WS according to any of various embodiments such as FIG. 3B, FIG. 3C, FIG. 4B, FIG. 4C, and FIG. 5A. The anti-bending structure WS included in the first substructure SST1 and the anti-bending structure WS included the second substructure SST2 may have different shapes. For example, the impurity regions IR1 of the first substructure SST1 and the impurity regions IR2 of the second substructure SST2 may extend in parallel directions to each other or in perpendicular directions to each other. In this example, the second substructure SST2 as described and shown in FIG. 7G includes the auxiliary layer AX2 and the impurity regions IR2 corresponding to the anti-bending structure WS shown in FIG. 3B.

The second structure STR2 includes the second substructure SST2, a lower insulating layer LIL on the second substructure SST2, and a peripheral circuit, for example, the peripheral circuit structure PC of FIG. 2, formed in the lower insulating layer LIL. The peripheral circuit includes a transistor TR, a peripheral contact plug PCT, and a peripheral line PL. The second structure STR2 includes a lower pad LPD exposed through an upper surface of the second structure STR2. The peripheral contact plug PCT, the peripheral line PL, and the lower pad LPD each include a conductive material.

Referring to FIG. 7H, the first structure STR1 may be vertically flipped or inverted and stacked on the second structure STR2. The first substructure SST1 is located at the top of the flipped first structure STR1. The upper pad UPD is exposed to a lower surface of the flipped first structure STR1. The first structure STR1, that may be flipped, is stacked on the second structure STR2 such that the upper pad UPD contacts the lower pad LPD.

Because bending of the structures STR1 and STR2 is mitigated by the impurity regions IR1 and IR2, the first structure STR1 is easily stacked on the second structure STR2. For example, when the first structure STR1 and the second structure STR2 are bent or curved in the X direction, bent or curved in the Y direction, or bent or curved in the X direction and the Y direction, stacking the structures STR1 and STR2 in parallel in the X-Y plane is difficult when the first structure STR1 does not include the first substructure SST1 and second structure STR2 does not include the second substructure SST2. According to the present disclosure, the first structure STR1 is stacked on the second structure STR2 because bending of the structures STR1 and STR2 is mitigated.

Referring to FIG. 7I, the first substructure SST1 located on the first structure STR1 is removed. For example, the auxiliary layer AX1, the impurity regions IR1, and the first substrate SUB1 of the first substructure SST1 are removed. As the first substructure SST1 is removed, the upper ends of the cell plugs CPL are exposed. For example, an end of each of the cell plugs CPL located in the first substrate SUB1 in FIG. 7H is exposed as the first substrate SUB1 is etched in FIG. 7I.

The channel layer CH of each of the cell plugs CPL is exposed. The end of each of the exposed cell plugs CPL is removed to expose the channel layers CH. Among the blocking layer BX, the charge trapping layer CT, and the tunneling layer TX included in each of the cell plugs CPL, an end extending through the stack structures STK1 and STK2 is removed. The channel layer CH included in each of the cell plugs CPL is exposed protruding through the stack structures STK1 and STK2.

Referring to FIG. 7J, a source layer SL is formed on the first structure STR1. The source layer SL covers the upper surface of the stack structures STK1 and STK2, the cell plugs CPL, and the separator SLI. The source layer SL overlaps the auxiliary layer AX2 and the impurity regions IR2 of the second substructure SST2 in the Z direction.

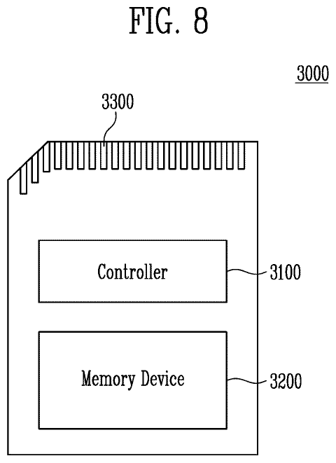

FIG. 8 is a diagram illustrating a memory card system 3000 including a memory device according to an embodiment of the present disclosure.

Referring to FIG. 8, the memory card system 3000 includes a controller 3100, a memory device 3200, and a connector 3300.

The controller 3100 is coupled to the memory device 3200. The controller 3100 is configured to access the memory device 3200. For example, the controller 3100 is configured to control a program operation, a read operation, an erase operation, and a background operation of the memory device 3200. The controller 3100 is configured to provide an interface between the memory device 3200 and a host. The controller 3100 may be configured to drive firmware that controls the memory device 3200. For example, the controller 3100 may include components such as a Random Access Memory (RAM), a processing unit, a host interface, a memory interface, and an error corrector.

The controller 3100 communicates with an external device through the connector 3300. The controller 3100 communicates with the external device, for example, the host, according to a specific communication protocol. For example, the controller 3100 may be configured to communicate with the external device through at least one of various communication protocols such as Universal Serial Bus (USB), Multi-Media Card (MMC), embedded MMC (eMMC), Peripheral Component Interconnection (PCI), PCI express (PCI-E), Advanced Technology Attachment (ATA), Serial-ATA (SATA), Parallel-ATA (PATA), Small Computer System Interface (SCSI), Enhanced Small Disk Interface (ESDI), Integrated Drive Electronics (IDE), Firewire, Universal Flash Storage (UFS), Wi-Fi, Bluetooth, and NVMe protocols. For example, the connector 3300 may be configured according to at least one of these communication protocols.

The memory device 3200 includes a plurality of memory cells and is configured having a similar structure as the memory device 100 shown in FIG. 1, FIG. 2, FIG. 3A, FIG. 4A, FIG. 5A, FIG. 6A, FIG. 6B, and/or FIG. 7J and formed utilizing the method of manufacturing a memory device according to the method described with reference to FIG. 7A through FIG. 7J.

The controller 3100 and the memory device 3200 are integrated into a single semiconductor device to constitute a memory card. For example, the controller 3100 and the memory device 3200 may constitute a memory card such as a personal computer (PC) card (Personal Computer Memory Card International Association (PCMCIA)), a Compact Flash (CF) card, a Smart Media Card (SM and SMC), a memory stick, a Multi-Media Card (MMC, RS-MMC, MMCmicro, or eMMC), an SD card (SD, miniSD, microSD, or SDHC), and a Universal Flash Storage (UFS).

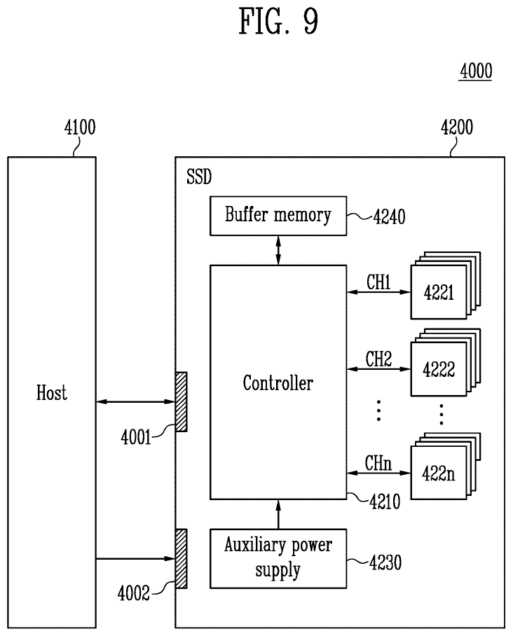

FIG. 9 is a diagram illustrating a solid state drive (SSD) system 4000 including a memory device according to an embodiment of the present disclosure.

Referring to FIG. 9, an SSD system 4000 includes a host 4100 and an SSD 4200. The SSD 4200 exchanges signals with the host 4100 through a signal connector 4001 and receives power through a power connector 4002. The SSD 4200 includes a controller 4210, a plurality of memory devices 4221 to 422n, an auxiliary power supply 4230, and a buffer memory 4240.

The controller 4210 controls the plurality of memory devices 4221 to 422n in response to signals received from the host 4100. For example, the signals may be based on an interface between the host 4100 and the SSD 4200. For example, the signals may be configured or constructed according to at least one of a plurality of interfaces such as Universal Serial Bus (USB), Multi-Media Card (MMC), embedded MMC (eMMC), Peripheral Component Interconnection (PCI), PCI express (PCI-E), Advanced Technology Attachment (ATA), Serial-ATA (SATA), Parallel-ATA (PATA), Small Computer System Interface (SCSI), Enhanced Small Disk Interface (ESDI), an Integrated Drive Electronics (IDE), Firewire, Universal Flash Storage (UFS), WI-FI, Bluetooth, and NVMe interfaces.

Each of the plurality of memory devices 4221 to 422n includes a plurality of memory cells configured to store data. Each of the plurality of memory devices 4221 to 422n may be configured in a similar manner as the memory device shown in FIG. 1, FIG. 2, FIG. 3A, FIG. 4A, FIG. 5A, FIG. 6A, FIG. 6B, and/or FIG. 7J and formed utilizing the method of manufacturing a memory device according to the method described with reference to FIG. 7A through FIG. 7J. The plurality of memory devices 4221 to 422n communicates with the controller 4210 through channels CH1 to CHn.

The auxiliary power supply 4230 is coupled to the host 4100 through a power connector 4002. The auxiliary power supply 4230 receives and is charged with power input from the host 4100. When the supply of power from the host 4100 is not smooth or consistent, the auxiliary power supply 4230 provides power to the SSD 4200. For example, the auxiliary power supply 4230 may be located inside or outside the SSD 4200. For example, the auxiliary power supply 4230 may be located on a main board and provide auxiliary power to the SSD 4200.

The buffer memory 4240 is a buffer memory for the SSD 4200. For example, the buffer memory 4240 temporarily stores data received from the host 4100 or data received from the plurality of memory devices 4221 to 422n or may temporarily store metadata, for example, mapping tables, of the memory devices 4221 to 422n. The buffer memory 4240 may include volatile memories such as DRAM, SDRAM, DDR SDRAM, and LPDDR SDRAM or non-volatile memories such as FRAM, ReRAM, STT-MRAM, and PRAM.

According to embodiments of the present disclosure, bending of a memory device may be reduced by forming impurity regions extending, for example, in one direction on or along a substrate.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to these descriptions. All changes within the meaning and range of equivalency of the claims are included within their scope.

What is claimed is:

1. A memory device comprising:
a stack structure including conductive layers alternately stacked with interlayer insulating layers in a third direction; and
an anti-bending structure overlapping the stack structure in the third direction, wherein the anti-bending structure includes:
an auxiliary layer; and
impurity regions within the auxiliary layer and including an impurity injected into the auxiliary layer.

2. The memory device of claim 1, further comprising a substrate overlapping the stack structure in the third direction,
wherein the anti-bending structure contacts a lower surface of the substrate.

3. The memory device of claim 1, further comprising a substrate overlapping the stack structure in the third direction,
wherein the anti-bending structure contacts an upper surface of the substrate.

4. The memory device of claim 1, wherein each of the conductive layers extends in a first direction, and
wherein each of the impurity regions extends in the first direction.

5. The memory device of claim 4, wherein the impurity regions apply a greater shrinkage stress than the stress applied by the auxiliary layer.

6. The memory device of claim 1, wherein each of the conductive layers extends in a first direction, and
wherein each of the impurity regions extends in a second direction perpendicular to the first direction.

7. The memory device of claim 6, wherein the impurity regions apply a greater expansion stress than the stress applied by the auxiliary layer.

8. The memory device of claim 1, further comprising a substrate overlapping the stack structure in the third direction,
wherein the anti-bending structure includes a first anti-bending structure spaced apart from a second anti-bending structure with the substrate disposed between the first anti-bending structure and the second anti-bending structure; and
wherein first impurity regions included in the first anti-bending structure extend in a first direction and the second impurity regions included in the second anti-bending structure extend in a second direction perpendicular to the first direction.

9. The memory device of claim 1, wherein the impurity regions are stripes extending in a first direction.

10. The memory device of claim 1, wherein the impurity regions are arranged in a dashed form having a major axis in a first direction.

11. The memory device of claim 1, wherein the impurity regions have a circular shape and are arranged in a first direction.

12. A memory device comprising:
a stack including conductive layers and interlayer insulating layers; and
an anti-bending structure disposed on the stack structure and including an auxiliary layer comprising impurity regions formed from an impurity injected into the auxiliary layer.
